(19) United States
(12) Patent Application Publication
(10) Pub. No.: US 2024/0422901 A1
(43) Pub. Date: Dec. 19, 2024

(54) PRINTED CIRCUIT BOARD

(71) Applicant: SAMSUNG ELECTRO-MECHANICS CO., LTD., Suwon-si (KR)

(72) Inventor: Jae Heun LEE, Suwon-si (KR)

(73) Assignee: SAMSUNG ELECTRO-MECHANICS CO., LTD., Suwon-si (KR)

(21) Appl. No.: 18/441,422

(22) Filed: Feb. 14, 2024

(30) Foreign Application Priority Data
Jun. 13, 2023 (KR) 10-2023-0075306

(51) Int. Cl. H05K 1/03; H05K 1/02; H05K 1/11; H05K 3/46

(52) U.S. Cl. CPC H05K 1/0306; H05K 1/0298; H05K 1/116; H05K 3/4647; H05K 3/4652

(57) ABSTRACT

A printed circuit board includes: a glass layer having a through-hole penetrating between an upper surface and a lower surface thereof; a through-via including a via metal layer disposed on a wall surface of the through-hole and a first insulating material disposed in at least a portion of a space between portions of the via metal layer in the through-hole; a first wiring layer disposed on the upper surface of the glass layer, at least a portion of the first wiring layer connected to an upper side of the through-via; a second wiring layer disposed on the lower surface of the glass layer, at least a portion of the second wiring layer connected to a lower side of the through-via; and a second insulating material covering at least a portion of an external surface of the glass layer. The first and second insulating materials include substantially the same material.

### CROSS-REFERENCE TO RELATED APPLICATION(S)

This application claims benefit of priority to Korean Patent Application No. 10-2023-0075306 filed on Jun. 13, 2023, in the Korean Intellectual Property Office, the disclosure of which is incorporated herein by reference in its entirety.

### TECHNICAL FIELD

The present disclosure relates to a printed circuit board.

Package technology continues to develop, and specifically, attempts to use silicon or glass to break away from the use of organic materials in traditional substrate manufacturing methods continue. However, in the case of a printed circuit board using a conventional glass core, a process of forming a through-via on a glass core may be somewhat complicated, and there may be a limit to implementing a fine line width directly in the glass core. In addition, the possibility of damage to the glass core during a process may be significantly high, and an exposed portion on a side surface of the glass core in a finished product may be vulnerable to impacts.

### SUMMARY

An aspect of the present disclosure is to provide a printed circuit board for forming a wiring layer formed on a glass layer into a microcircuit.

Another aspect of the present disclosure is to provide a printed circuit board capable of simplifying a process and being advantageous for warpage control.

Another aspect of the present disclosure is to provide a printed circuit board for preventing damage to a glass layer and protecting an external surface of the glass layer.

One of the various solutions proposed through the present disclosure is to form a through-via on a glass layer and then flatten the through-via using Chemical Mechanical Polishing (CMP) to form a circuit with a Semi Additive Process (SAP) on the glass layer.

Another of the various solutions proposed through the present disclosure is to simultaneously perform a glass layer embedding process and a through-hole plugging process of a glass layer.

Another of the various solutions proposed through the present disclosure is to perform a glass layer embedding process and a through-hole plugging process using a reinforcing layer such as Copper Clad Laminate (CCL) as a jig.

According to an aspect of the present disclosure, a printed circuit board may include: a glass layer having a through-hole penetrating between an upper surface and a lower surface thereof; a through-via including a via metal layer disposed on a wall surface of the through-hole and a first insulating material disposed in at least a portion of a space between portions of the via metal layer in the through-hole; a first wiring layer disposed on the upper surface of the glass layer, at least a portion of the first wiring layer being connected to an upper side of the through-via; a second wiring layer disposed on the lower surface of the glass layer, at least a portion of the second wiring layer being connected to a lower side of the through-via; and a second insulating material covering at least a portion of an external surface of the glass layer. The first and second insulating materials may include substantially the same material.

According to another aspect of the present disclosure, a printed circuit board may include: a through-via including a via metal layer and a first insulating material disposed in at least a portion of a space between portions of the via metal layer; a glass layer including a first through-portion in which the through-via is disposed; a second insulating material including a second through-portion in which the through-via and the glass layer are disposed; a first wiring layer disposed on an upper surface of the glass layer, at least a portion of the first wiring layer being connected to an upper side of the through-via; a second wiring layer disposed on a lower surface of the glass layer, at least a portion of the second wiring layer being connected to a lower side of the through-via; a first insulating layer disposed on upper surfaces of each of the glass layer and the second insulating material, and covering at least a portion of the first wiring layer; and a second insulating layer disposed on lower surfaces of each of the glass layer and the second insulating material, and covering at least a portion of the second wiring layer. The first and second insulating materials may include substantially the same material.

According to another aspect of the present disclosure, a printed circuit board may include: a glass layer having a through-hole penetrating between an upper surface and a lower surface thereof; a through-via including a via metal layer disposed on a wall surface of the through-hole and a first insulating material disposed in at least a portion of a space between portions of the via metal layer in the through-hole; a first wiring layer disposed on the upper surface of the glass layer, at least a portion of the first wiring layer being connected to an upper side of the through-via; a second wiring layer disposed on the lower surface of the glass layer, at least a portion of the second wiring layer being connected to a lower side of the through-via; and a second insulating material including a through-hole in which the glass layer is disposed and being in contact with the glass layer. Upper surfaces of each of the glass layer, the first insulating material, the second insulating material, and the via metal layer may be substantially coplanar with each other.

One of the various effects of the present disclosure is to provide a printed circuit board capable of forming a wiring layer formed on a glass layer into a microcircuit.

Another of the various effects of the present disclosure is to provide a printed circuit board capable of simplifying a process and advantageous for warpage control.

Another of the various effects of the present disclosure is to provide a printed circuit board capable of preventing damage to a glass layer and protecting an external surface of the glass layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a schematic cut plan view taken along line I-I′ of the printed circuit board of FIG. 3;

FIGS. 5A to 5I are process diagrams schematically illustrating an example of manufacturing the printed circuit board of FIG. 3;

FIG. 6 is a cross-sectional view schematically illustrating another example of a printed circuit board;

FIG. 7 is a schematic cut plan view taken along line II-II′ of the printed circuit board of FIG. 6;

FIGS. 8A and 8B are process diagrams schematically illustrating an example of manufacturing the printed circuit board of FIG. 6;

FIG. 9 is a cross-sectional view schematically illustrating another example of a printed circuit board;

FIGS. 10A and 10B are process diagrams schematically illustrating an example of manufacturing the printed circuit board of FIG. 9;

FIG. 11 is a cross-sectional view schematically illustrating another example of a printed circuit board; and

FIGS. 12A and 12B are process diagrams schematically illustrating an example of manufacturing the printed circuit board of FIG. 11.

### DETAILED DESCRIPTION

Hereinafter, the present disclosure will be described with reference to the accompanying drawings. In the drawings, the shape and size of the elements may be exaggerated or reduced for clearer description.

### Electronic Device

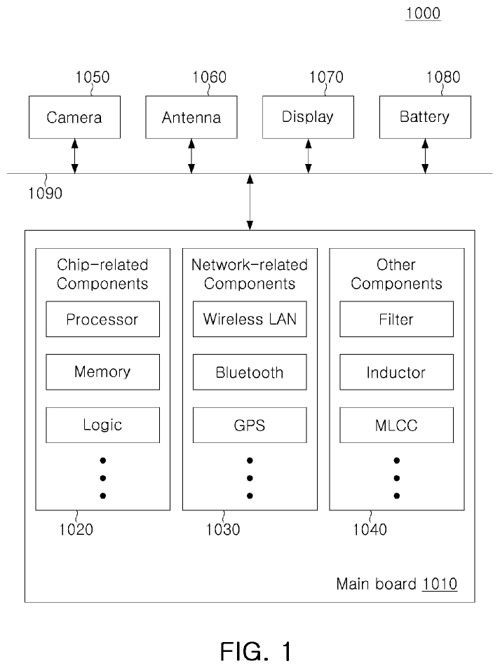

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may be in the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. Furthermore, these other electronic components may also other electronic components used for various purposes depending on a type of electronic device 1000.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

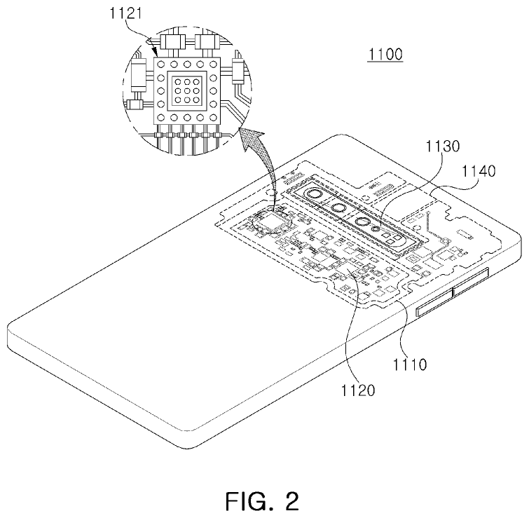

FIG. 2 is a perspective view schematically illustrating an example of an electronic device.

Referring to FIG. 2, an electronic device may be, for example, a smartphone 1100. A motherboard 1110 may be accommodated in the smartphone 1100, and various components 1120 may be physically and/or electrically connected to the motherboard 1110. Furthermore, other components that may or may not be physically and/or electrically connected to the motherboard 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may be in the form of a printed circuit board in which an electronic component including an active component and/or a passive component is mounted on a surface. Alternatively, the component package 1121 may be in the form of a printed circuit board in which an active component and/or a passive component are embedded. On the other hand, the electronic device is not necessarily limited to the smartphone 1100, and may be other electronic devices as described above.

### Printed Circuit Board

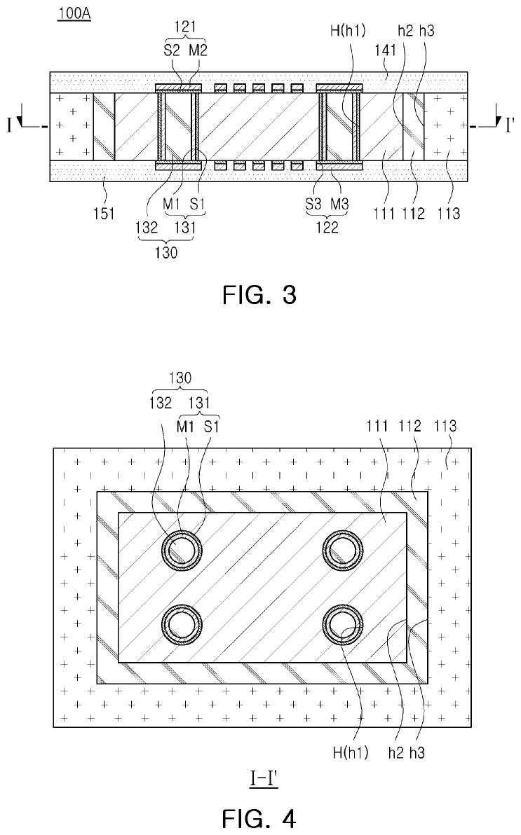

FIG. 3 is a cross-sectional view schematically illustrating an example of a printed circuit board.

FIG. 4 is a schematic cut plan view taken along line I-I′of the printed circuit board of FIG. 3.

Referring to the drawings, a printed circuit board 100A according to an example embodiment may include a glass layer 111 having a through-hole H penetrating between an upper surface and a lower surface, a through-via 130 including a via metal layer 131 disposed on a wall surface of the through-hole H and a first insulating material 132 filling at least a portion of a space G between the via metal layers 131 in the through-hole H, a first wiring layer 121 disposed on the upper surface of the glass layer 111 and having at least a portion connected to an upper side of the through-via 130, a second wiring layer 122 disposed on the lower surface of the glass layer 111 and having at least a portion connected to a lower side of the through-via 130, a second insulating material 112 covering at least a portion of an external surface of the glass layer 111, a third insulating material 113 covering at least a portion of an external surface of the second insulating material 112, a first insulating layer 141 disposed on upper surfaces of each of the glass layer 111, the second insulating material 112 and the third insulating material 113 and covering at least a portion of the first wiring layer 121, and a second insulating layer 151 disposed on lower surfaces of each of the glass layer 111, the second insulating material 112 and the third insulating material 113 and covering at least a portion of the second wiring layer 122.

The through-hole H of the glass layer 111 may be a first through-portion h1. A through-via 130 including a via metal layer 131 and a first insulating material 132 may be disposed in the first through-portion h1. Similarly, the second insulating material 112 may have a second through-portion h2. The through-via 130 including a via metal layer 131 and a first insulating material 132, and the glass layer 111 may be disposed in the second through-portion h2. From a similar viewpoint, the third insulating material 113 may have a third through-portion h3. In the third through-portion h3, the through-via 130 including the via metal layer 131 and the first insulating material 132, the glass layer 111, and the second insulating material 112 may be disposed.

The first and second insulating materials 132 and 112 may include substantially the same material. For example, the first and second insulation materials 132 and 112 may be formed by simultaneously performing an embedding process of the glass layer 111 and a plugging process of the through-hole H through an Ajinomoto Build-up Film (ABF), as exemplarily disclosed in a process described below, and may include substantially the same material. Furthermore, the first and second insulation materials 132 and 112 may have substantially the same degree of hardening. Accordingly, a process thereof may be further simplified, and furthermore, warpage control may be more advantageous in the process. The fact that the embedding and the plugging were formed simultaneously with substantially the same material, such as the ABF, may be confirmed by analyzing a size and dispersion of a filler in the ABF or the degree of resin hardening (measured by FT-IR, etc.).

The third insulating material 113 may include a material different from those of the first and second insulating materials 132 and 112. For example, the third insulating material 113 may have a greater elastic modulus than the first and second insulating materials 132 and 112. The elastic modulus may denote a ratio of stress to strain, and as a measurement method, for example, the elastic modulus may be measured through a standard tensile test specified in JISC-6481, KS M 3001, KS M 527-3, ASTM D882, and the like. For example, the third insulating material 113 may include a material having excellent rigidity, such as an insulating material of a copper clad laminate (CCL), as exemplarily disclosed in the process described below. In this case, a glass layer 111 embedding process and a through-hole H plugging process may be performed using the third insulating material 113 as a jig. Accordingly, it may be possible to prevent the glass layer from being damaged during the process, and it may be possible to protect an external surface of the glass layer together with the second insulating material 112.

The via metal layer 131 may include a first seed layer S1 disposed on a wall surface of the through-hole H and a first metal layer M1 disposed on a side surface of the first seed layer S1. The first wiring layer 121 may include a second seed layer S2 disposed on an upper surface of the glass layer 111 and a second metal layer M2 disposed on an upper surface of the second seed layer S2. The second wiring layer 122 may include a third seed layer S3 disposed on a lower surface of the glass layer 111 and a third metal layer M3 disposed on a lower surface of the third seed layer S3. At least a portion of the first wiring layer 121 may be configured such that the second seed layer S2 covers at least a portion of upper surfaces of each of the first seed layer S1, the first metal layer M1 and the first insulating material 132. At least a portion of the second wiring layer 122 may be configured such that the third seed layer S3 covers at least a portion of lower surfaces of each of the first seed layer S1, the first metal layer M1 and the first insulating material 132. The first seed layer S1 may have boundaries with the second and third seed layers S2 and S3, respectively.

Upper surfaces of each of the glass layer 111, the first insulating material 132, the second insulating material 112, the first seed layer S1, and the first metal layer M1 may be substantially coplanar with each other. For example, upper surfaces of each of the glass layer 111, the via metal layer 131, the first insulating material 132, the second insulating material 112, and the third insulating material 113 may be substantially coplanar with each other. Lower surfaces of each of the glass layer 111, the first insulating material 132, the second insulating material 112, the first seed layer S1, and the first metal layer M1 may substantially coplanar with each other. For example, lower surfaces of each of the glass layer 111, the via metal layer 131, the first insulating material 132, the second insulating material 112, and the third insulating material 113 may substantially coplanar with each other. For example, as exemplarily disclosed in a process described below, the through-via 130 may be formed on the glass layer 111 and then flattened using chemical mechanical polishing (CMP). In this case, a circuit may be formed on the glass layer by a semi additive process (SAP) rather than a tenting.

Accordingly, the first and second wiring layers 121 and 122 may be formed of a microcircuit. Accordingly, pads of the first and second wiring layers 121 and 122 may be directly formed on the through-via 130 to secure a degree of freedom in terms of design.

Hereinafter, components of the printed circuit board 100A according to an example embodiment will be described in more detail with reference to the drawings.

The glass layer 111 may include glass that is an amorphous solid. Glass may include, for example, pure silicon dioxide (about 100% SiO₂), soda lime glass, borosilicate glass, and alumino-silicate glass. However, the present disclosure is not limited thereto, and alternative glass materials, such as fluorine glass, phosphoric acid glass, chalcogen glass, or the like, may also be used as materials. Other additives may also be included to form glass with specific physical properties. These additives may include not only calcium carbonate (e.g., lime) and sodium carbonate (e.g., soda), but also magnesium, calcium, manganese, aluminum, lead, boron, iron, chromium, potassium, sulfur and antimony, and carbonate and/or oxides of these elements and other elements.

The glass layer 111 may be a layer distinct from organic insulating materials including glass fibers (Glass Fiber, Glass Cloth and Glass Fabric), such as Copper Clad Laminate (CCL) and Prepreg (PPG). For example, the glass layer 111 may include plate glass. The glass layer 111 may be a core layer, and may be, for example, a glass core.

The through-hole H may penetrate through the glass layer 111 in a thickness direction. For example, the through-hole H may penetrate between the upper and lower surfaces of the glass layer 111. The through-hole H may have one or more holes. The through-hole H may be in the form of an elliptical column or a circular column, but is not limited thereto, and may be in the form of an hourglass column or the like.

The first to third seed layers S1, S2 and S3 may include copper (Cu), aluminum (Al), silver (Ag), tin (Sn), gold (Au), nickel (Ni), lead (Pb), titanium (Ti), and/or alloys thereof, respectively, and may preferably include copper (Cu), but the present disclosure is not limited thereto. The first to third seed layers S1, S2 and S3 may be distinct layers having boundaries with each other. The first to third seed layers S1, S2 and S3 may be formed by electroless plating (e.g., chemical copper plating) and/or sputtering, respectively. The first to third seed layers S1, S2 and S3 may be thinner than the first to third metal layers M1, M2 and M3, respectively.

The first to third metal layers M1, M2 and M3 may include copper (Cu), aluminum (Al), silver (Ag), tin (Sn), gold (Au), nickel (Ni), lead (Pb), titanium (Ti), and/or alloys thereof, respectively, and may preferably include copper (Cu), but the present disclosure is not limited thereto. Each of the first to third metal layers M1, M2 and M3 may be formed by electroplating (e.g., electro-copper plating). The first to third metal layers M1, M2 and M3 may be thicker than the first to third seed layers S1, S2 and S3, respectively.

Each of the first and second wiring layers 121 and 122 may perform various functions according to a design. For example, the first and second wiring layers 121 and 122 may include signal patterns, power patterns, and ground patterns, and each of these patterns may have various shapes such as a line (or trace), a plane (or plate), and a pad (or land). Each of the first and second wiring layers 121 and 122 may include an electroless plating layer (or chemical copper) and an electrolytic plating layer (or electric copper). If necessary, the first and second wiring layers 121 and 122 may include a sputtering layer instead of an electroless plating layer (or chemical copper), or both an electroless plating layer (or chemical copper) and a sputtering layer.

The via metal layer 131 may perform various functions according to a design. For example, the via metal layer 131 may include a ground via, a power via, and a signal via. The via metal layer 131 may include an electroless plating layer (or chemical copper) and an electrolytic plating layer (or electro-copper). If necessary, the via metal layer 131 may include a sputtering layer instead of an electroless plating layer (or chemical copper), or both an electroless plating layer (or chemical copper) and a sputtering layer.

The first to third insulation materials 132, 112 and 113 may include organic insulation materials identical to or different from each other. The organic insulation materials may include a thermosetting resin such as an epoxy resin, a thermoplastic resin such as polyimide, or materials including inorganic fillers, organic fillers, and/or glass fibers (Glass Fiber, Glass Cloth and Glass Fabric) along with the resin. For example, the organic insulating material may be a non-photosensitive insulating material such as an Ajinomoto Build-up Film (ABF), Prepreg (PPG), and Copper Clad Laminate (CCL), but the present disclosure is not limited thereto, and other polymer materials may be used as the organic insulating material. Furthermore, the organic insulating material may be a photosensitive insulating material such as a photoimageable dielectric (PID).

The first and second insulating layers 141 and 142 may also include the organic insulating material described above. The first and second insulating layers 141 and 142 may include substantially the same material. If necessary, the first and second insulating layers 141 and 142 may include substantially the same material as the first and second insulating materials 132 and 112. Even in this case, the first and second insulating layers 141 and 142 may be separated from the first and second insulating materials 132 and 112 by boundaries.

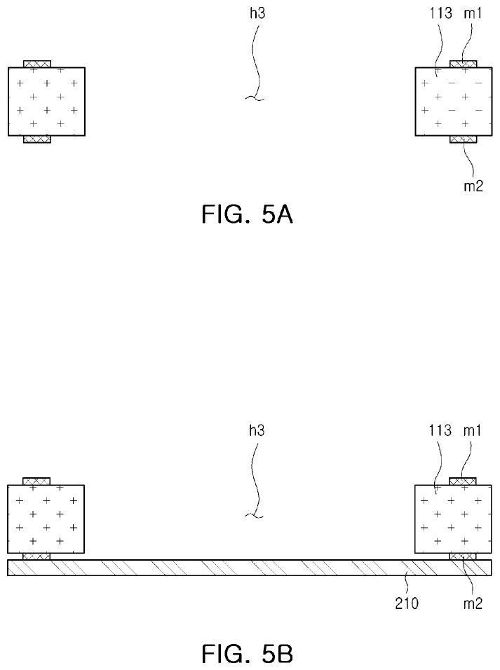

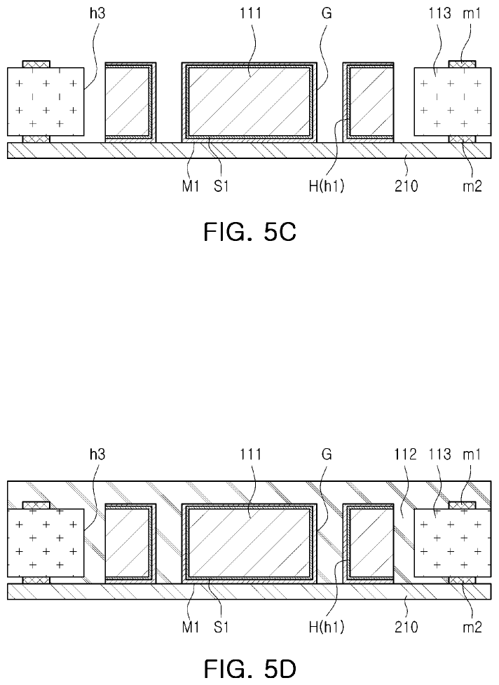

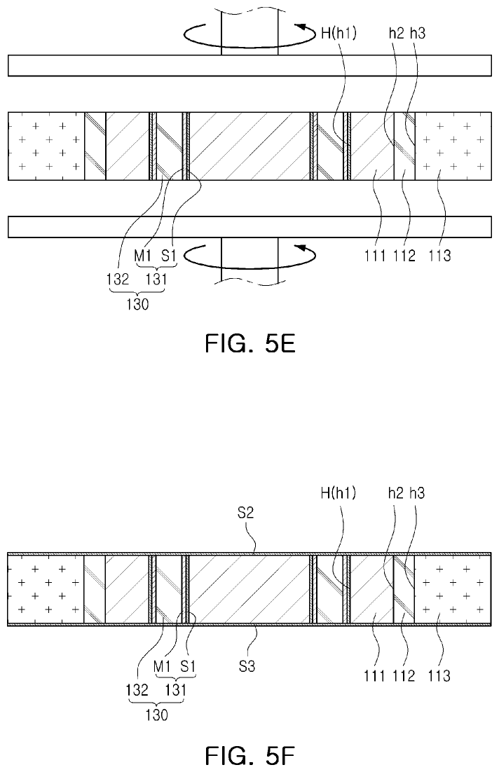

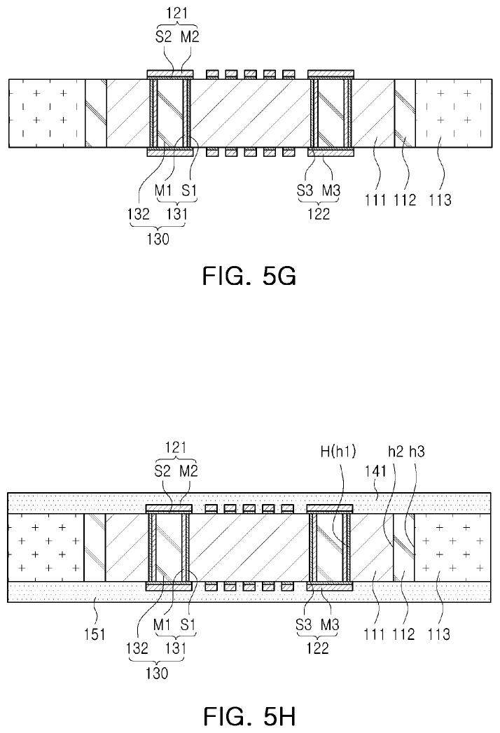

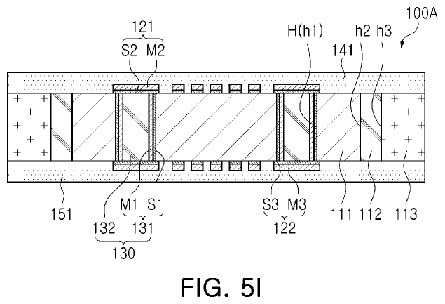

FIGS. 5A to 5I are process diagrams schematically showing an example of manufacturing the printed circuit board of FIG. 3.

Referring to FIG. 5A, a third insulating material 113 having a third through-portion h3 formed thereon is prepared. The third insulating material 113 may be an insulating material of the Copper Clad Laminate (CCL) as described above, but the present disclosure is not limited thereto. First and second mark patterns m1 and m2 may be formed on an upper surface and a lower surface of the third insulating material 113, respectively, from which the third through-portion h3 may be more precisely formed at a desired position. The third insulating material 113 may be a panel level layer, and in this case, a plurality of third through-portions h3 may be provided. The third insulating material 113 may be used as a jig.

Referring to FIG. 5B, a tape 210 is attached to a lower side of the third insulating material 113. The tape 210 may block a lower side of the third through-portion h3. The tape 210 may be a known adhesive, for example, an epoxy material, but is not limited thereto.

Referring to FIG. 5C, a glass layer 111 with a first through-portion h1 formed is prepared, and a first seed layer S1 and a first metal layer M1 are sequentially formed on the glass layer 111 through electroless plating, electrolytic plating, and the like. Next, the glass layer 111 in which the first through-portion h1, the first seed layer S1 and the first metal layer M1 are formed is disposed on the third through-portion h3 of the third insulating material 113 using the tape 210. When a plurality of third through-portions h3 are provided, a plurality of glass layers 111 in which the first through-portion h1, the first seed layer S1 and the first metal layer M1 are formed may be prepared and then disposed on each of the third through-portions h3.

Referring to FIG. 5D, a second insulating material 112 is laminated to perform an embedding process of the glass layer 111, and at the same time, a plugging process of the first through-portion h1 is performed. For example, through a lamination process, the second insulating material 112 may cover at least a portion of each of the glass layer 111 and the third insulating material 113, and may fill at least a portion of a space G between the first metal layers M1 in the first through-portion h1.

Referring to FIG. 5E, after removing the tape 210, upper and lower surfaces of each of the glass layer 111, the first seed layer S1, the first metal layer M1, the second insulating material 112, and the third insulating material 113 are planarized through a planarization process such as chemical mechanical polishing (CMP). For example, the first seed layer S1, the first metal layer M1, and the first and second mark patterns m1 and m2 disposed on the upper and lower surfaces of each of the glass layer 111, the second insulating material 112, and the third insulating material 113 may be removed in a planarization process. As a result, a through-via 130 including a via metal layer 131 and a first insulating material 132 may be formed. Furthermore, the second insulating material 112 may have a second through-portion h2 afterwards.

Referring to FIG. 5F, second and third seed layers S2 and S3 are formed on upper and lower surfaces of each of the planarized glass layer 111, the planarized first seed layer S1, the planarized first metal layer M1, the planarized first insulating material 132, the planarized second insulating material 112, and the planarized third insulating material 113 through electroless plating or the like.

Referring to FIG. 5G, second and third metal layers M2 and M3 are formed on the second and third seed layers S2 and S3, respectively, through electroplating or the like. For example, a semi additive process (SAP) may be applied, and accordingly, first and second wiring layers 121 and 122 including microcircuits may be formed.

Referring to FIG. 5H, first and second insulation layers 141 and 151 are formed on upper and lower surfaces of each of the glass layer 111, the second insulation material 112, and the third insulation material 113, respectively, through a lamination process.

Referring to FIG. 5I, at least a portion of each of the third insulating material 113 and the first and second insulating layers 141 and 151 is cut. Through a series of processes, the printed circuit board 100A according to the above-described embodiment may be manufactured. As described above, when the third insulating material 113 is on a panel level, a cutting process may include singulation, thereby forming a plurality of substrate units.

Other contents are substantially the same as described in the printed circuit board 100A according to the aforementioned example embodiment, and thus overlapping descriptions thereof are omitted.

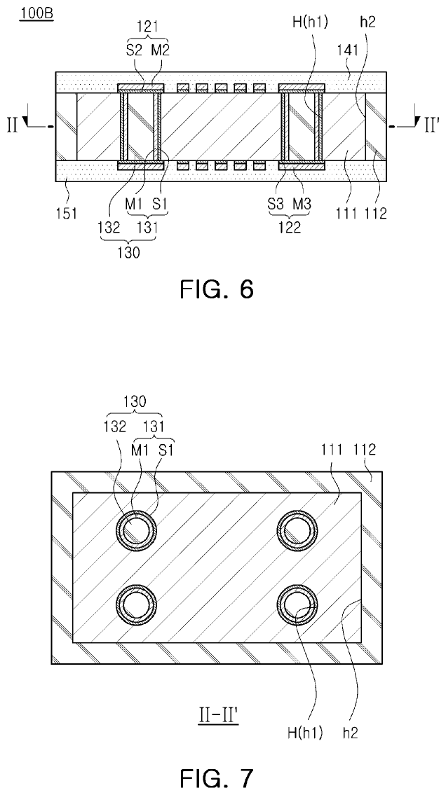

FIG. 6 is a cross-sectional view schematically illustrating another example of a printed circuit board.

FIG. 7 is a schematic cut plan view taken along line II-II′ of the printed circuit board of FIG. 6.

Referring to the drawings, in a printed circuit board 100B according to another example embodiment, a third insulating material 113 is omitted in the printed circuit board 100A according to the aforementioned example embodiment. For example, a second insulating material 112 may be disposed on the outermost side of the board. Accordingly, the board may be manufactured more compactly.

Other contents are substantially the same as described in the printed circuit board 100A according to the aforementioned example embodiment, and thus overlapping descriptions thereof are omitted.

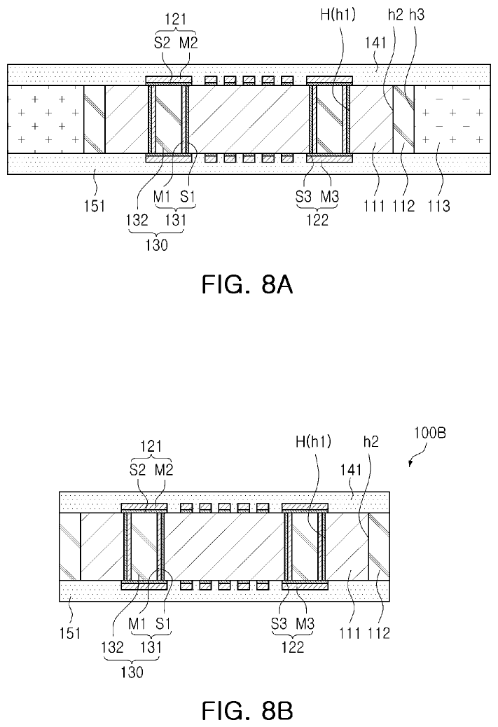

FIGS. 8A and 8B are process diagrams schematically illustrating an example of manufacturing the printed circuit board of FIG. 6.

Referring to FIG. 8A, a stacked body before a cutting process is formed through the substantially same process as those of FIGS. 5A to 5H described above.

Referring to FIG. 8B, at least a portion of each of a third insulating material 113 and first and second insulating layers 141 and 151 is cut so that the third insulating material 113 does not remain on a substrate. Through a series of processes, a printed circuit board 100B according to another example embodiment described above may be manufactured. As described above, when the third insulating material 113 is on a panel level, a cutting process may include singulation, thereby forming a plurality of substrate units.

Other contents are substantially the same as described in the printed circuit board 100A according to the aforementioned example embodiment and manufacturing examples thereof, and thus overlapping descriptions thereof are omitted.

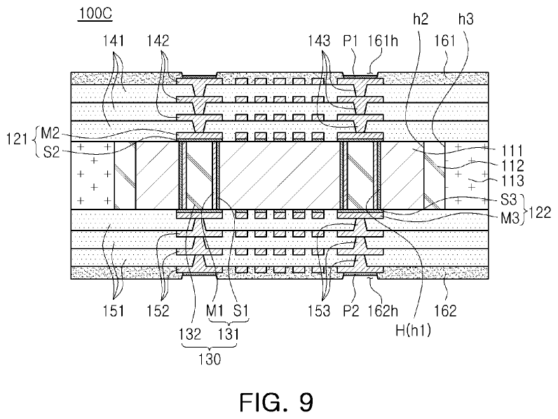

FIG. 9 is a cross-sectional view schematically illustrating another example embodiment of a printed circuit board.

Referring to FIG. 9, a printed circuit board 100C according to another example embodiment is configured so that in the printed circuit board 100A according to the above-described example embodiment, first and second insulating layers 141 and 151 are disposed in a plurality of layers, respectively. Furthermore, the printed circuit board 100C further includes a plurality of third wiring layers 142 disposed on or within the plurality of first insulating layers 141, and a plurality of fourth wiring layers 152 disposed on or within a plurality of second insulating layers 151. Furthermore, the printed circuit board 100C further includes a plurality of first via layers 143 penetrating through at least one of the plurality of first insulating layers 141, and a plurality of second via layers 153 penetrating through at least one of the plurality of second insulating layers 151. Furthermore, the printed circuit board 100C further includes a first resist layer 161 disposed on an upper surface of a first insulating layer 141 disposed on an uppermost side of the plurality of first insulating layers 141 and having a first opening 161h exposing at least a portion of a third wiring layer 142 disposed on an uppermost side of the plurality of third wiring layers 142, and a second resist layer 162 disposed on a lower surface of a second insulating layer 151 disposed on a lowermost side of the plurality of second insulating layers 151 and having a second opening 162h exposing at least a portion of a fourth wiring layer 152 disposed on a lowermost side of the plurality of fourth wiring layers 152.

Each of the plurality of third and fourth wiring layers 142 and 152 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but is not limited thereto. Each of the plurality of third and fourth wiring layers 142 and 152 may perform various functions according to a design. For example, the plurality of third and fourth wiring layers 142 and 152 may include a signal pattern, a power pattern, and a ground pattern. Each of these patterns may have various shapes such as a line, a plane, and a pad. Each of the plurality of third and fourth wiring layers 142 and 152 may include an electroless plating layer (or chemical copper) and an electrolytic plating layer (or electric copper). Alternatively, the plurality of third and fourth wiring layers 142 and 152 may include a metal foil (or a copper foil) and an electroplating layer (or electric copper). Alternatively, the plurality of third and fourth wiring layers 142 and 152 may include a metal foil (or a copper foil), an electroless plating layer (or chemical copper), and an electrolytic plating layer (or electro copper). Instead of the electroless plating layer (or chemical copper), a sputtering layer may be included therein, or both may be included therein.

Each of the plurality of first and second via layers 143 and 153 may include a metal. The metal may include copper (Cu), aluminum (Al), silver (Ag), tin (Sn), gold (Au), nickel (Ni), lead (Pb), titanium (Ti), and/or alloys thereof. The metal may include, preferable, copper (Cu) may be included, but is not limited thereto. Each of the plurality of first and second via layers 143 and 153 may include a field via filling a via hole, but may also include a conformal via disposed along a wall surface of the via hole. The first and second via layers 143 and 153 may perform various functions according to a design. For example, the first and second via layers 143 and 153 may include a ground via, a power via, and a signal via. The plurality of first and second via layers 143 and 153 may have tapered shapes in opposite directions on a cross-section. Each of the plurality of first and second via layers 143 and 153 may include an electroless plating layer (or chemical copper) and an electrolytic plating layer (or electro copper). Instead of the electroless plating layer (or chemical copper), a sputtering layer may be included therein, or both may be included therein.

The first and second resist layers 161 and 162 may include a liquid or film type solder resist, but are not limited thereto, and other types of insulating materials may be used. Surface treatment layers P1 and P2 may be formed on a pattern exposed to the first opening 161h and/or the second opening 162h, as necessary.

Other contents are substantially the same as described in the printed circuit board 100A according to the aforementioned example embodiment, and thus overlapping descriptions thereof are omitted.

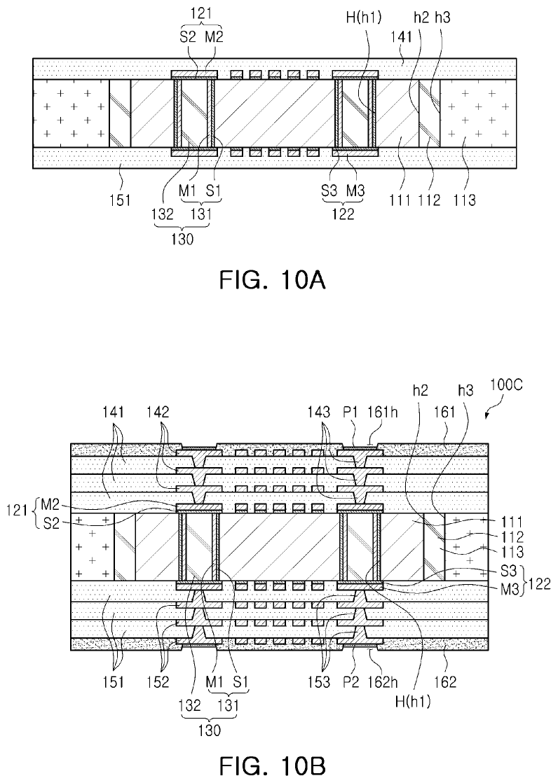

FIGS. 10A and 10B are process diagrams schematically illustrating an example of manufacturing the printed circuit board of FIG. 9.

Referring to FIG. 10A, a stacked body before a cutting process is formed through substantially the same process as those of FIGS. 5A to 5H described above.

Referring to FIG. 10B, a plurality of first and second insulating layers 141 and 151, a plurality of third and fourth wiring layers 142 and 152, a plurality of first and second via layers 143 and 153, and first and second resist layers 161 and 162 are formed through a build-up process. Next, at least a portion of each of the third insulating material 113, the plurality of first and second insulating layers 141 and 151, and the first and second resist layers 161 and 162 is cut. Through a series of processes, the printed circuit board 100C according to another example embodiment described above may be manufactured. As described above, when the third insulating material 113 is on a panel level, a cutting process may include singulation, thereby forming a plurality of substrate units.

Other contents are substantially the same as described in the printed circuit board 100A according to the aforementioned example embodiment and manufacturing examples thereof, and thus overlapping descriptions thereof are omitted.

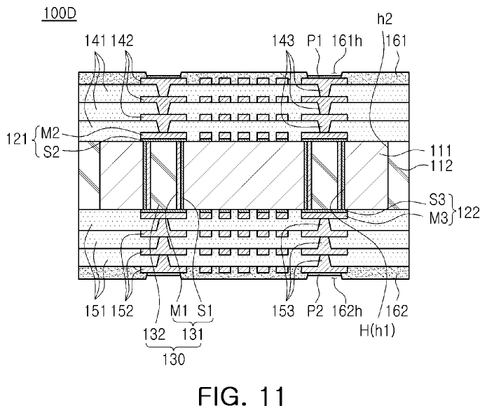

FIG. 11 is a cross-sectional view schematically illustrating another example embodiment of a printed circuit board.

Referring to FIG. 11, a printed circuit board 100D according to another example embodiment is configured so that in the printed circuit board 100B according to the above-described example embodiment, first and second insulating layers 141 and 151 are disposed in a plurality of layers, respectively. Furthermore, the printed circuit board 100D further includes a plurality of third wiring layers 142 disposed on or within the plurality of first insulating layers 141, and a plurality of fourth wiring layers 152 disposed on or within the plurality of second insulating layers 151. Furthermore, the printed circuit board 100D further includes a first resist layer 161 disposed on an upper surface of a first insulating layer 141 disposed on an uppermost side of the plurality of first insulating layers 141 and having a first opening 161h exposing at least a portion of a third wiring layer 142 disposed on an uppermost side of the plurality of third wiring layers 142, and a second resist layer 162 disposed on a lower surface of a second insulating layer 151 disposed on an uppermost side of the plurality of second insulating layers 151 and having a second opening 162h exposing at least a portion of a fourth wiring layer 152 disposed on a lowermost side of the plurality of fourth wiring layers 152.

Other contents are substantially the same as those described in the printed circuit boards 100A, 100B and 100C described above, and thus overlapping description thereof will be omitted.

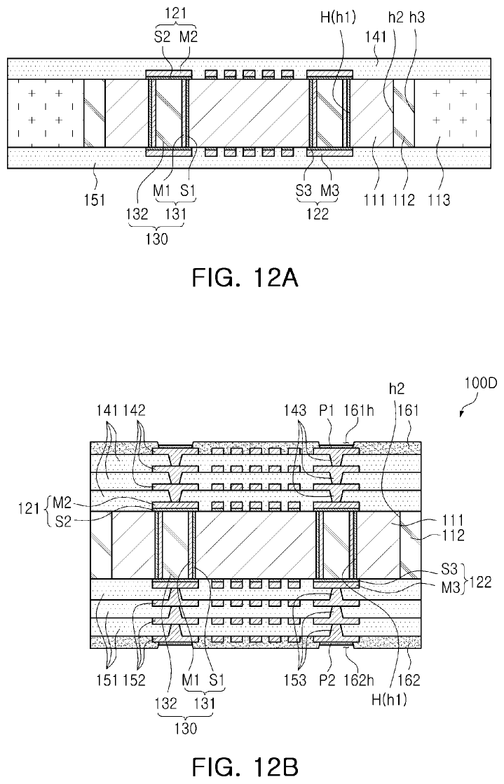

FIGS. 12A and 12B are process diagrams schematically illustrating an example of manufacturing the printed circuit board of FIG. 11.

Referring to FIG. 12A, a stacked body before a cutting process is formed through the substantially same process as those of FIGS. 5A to 5H described above.

Referring to FIG. 12B, a plurality of first and second insulating layers 141 and 151, a plurality of third and fourth wiring layers 142 and 152, a plurality of first and second via layers 143 and 153, and first and second resist layers 161 and 162 are formed through a build-up process. Next, at least a portion of each of a third insulating material 113, the plurality of first and second insulating layers 141 and 151, and the first and second resist layers 161 and 162 is cut so that the third insulating material 113 does not remain on a substrate. Through a series of processes, the printed circuit board 100D according to another example embodiment described above may be manufactured. As described above, when the third insulating material 113 is on a panel level, a cutting process may include singulation, thereby forming a plurality of substrate units.

Other contents are substantially the same as those described in the printed circuit boards 100A, 100B and 100C described above and manufacturing examples thereof, and thus overlapping descriptions thereof are omitted.

In the present disclosure, a depth, a thickness, a width, and a length may be measured by a scanning microscope or an optical microscope based on a cross-section obtained by polishing or cutting each of printed circuit boards. The cut cross-section may be a vertical cross-section or a horizontal cross-section, and each numerical value may be measured based on a required cut cross-section. If a value is not constant, the value may be determined as an average value of values measured at any five random points.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist.

In the present disclosure, substantially, determination may be performed by including a process error or a positional deviation occurring in a manufacturing process, and an error during measurement. For example, being substantially coplanar may include not only a case in which components exist on the completely same plane, but also a case in which components exist on substantially the same plane. Furthermore, substantially the same material may include not only a case in which a composition and a degree of curing of a material are completely the same, but also a case in which they are substantially the same.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board comprising:
a glass layer having a through-hole penetrating between an upper surface and a lower surface thereof;
a through-via including a via metal layer disposed on a wall surface of the through-hole and a first insulating material disposed in at least a portion of a space between portions of the via metal layer in the through-hole;
a first wiring layer disposed on the upper surface of the glass layer, at least a portion of the first wiring layer being connected to an upper side of the through-via;
a second wiring layer disposed on the lower surface of the glass layer, at least a portion of the second wiring layer being connected to a lower side of the through-via; and
a second insulating material covering at least a portion of an external surface of the glass layer,
wherein the first and second insulating materials include substantially the same material.

2. The printed circuit board according to claim 1, wherein the glass layer includes plate glass.

3. The printed circuit board according to claim 1, wherein the via metal layer includes a first seed layer disposed on the wall surface of the through-hole and a first metal layer disposed on a side surface of the first seed layer,
the first wiring layer includes a second seed layer disposed on the upper surface of the glass layer and a second metal layer disposed on an upper surface of the second seed layer, and
the second wiring layer includes a third seed layer disposed on the lower surface of the glass layer and a third metal layer disposed on a lower surface of the third seed layer.

4. The printed circuit board according to claim 3, wherein the second seed layer covers at least a portion of upper surfaces of each of the first seed layer, the first metal layer, and the first insulating material, and
the third seed layer covers at least a portion of lower surfaces of each of the first seed layer, the first metal layer, and the first insulating material.

5. The printed circuit board according to claim 4, wherein the first seed layer has boundaries with the second and third seed layers, respectively.

6. The printed circuit board according to claim 4, wherein upper surfaces of each of the glass layer, the first insulating material, the second insulating material, the first seed layer and the first metal layer are substantially coplanar with each other, and
lower surfaces of each of the glass layer, the first insulating material, the second insulating material, the first seed layer, and the first metal layer are substantially coplanar to each other.

7. The printed circuit board according to claim 1, further comprising:
a third insulating material covering at least a portion of an external surface of the second insulating material,
wherein the third insulating material includes a material different from the first and second insulating materials.

8. The printed circuit board according to claim 7, wherein the third insulating material has an elastic modulus greater than that of the first and second insulating materials.

9. The printed circuit board according to claim 7, wherein upper surfaces of each of the glass layer, the via metal layer, the first insulating material, the second insulating material and the third insulating material are substantially coplanar with each other, and
lower surfaces of each of the glass layer, the via metal layer, the first insulating material, the second insulating material and the third insulating material are substantially coplanar to each other.

10. The printed circuit board according to claim 1, further comprising:
one or more first insulating layers disposed on upper surfaces of each of the glass layer and the second insulating material, and covering at least a portion of the first wiring layer; and
one or more second insulating layers disposed on lower surfaces of each of the glass layer and the second insulating material, and covering at least a portion of the second wiring layer.

11. The printed circuit board according to claim 10, further comprising:
one or more third wiring layers disposed on or within the one or more first insulating layers;
one or more first via layers penetrating through at least one of the one or more first insulating layers, respectively;
one or more fourth wiring layers disposed on or within the one or more second insulating layers; and
one or more second via layers penetrating through at least one of the one or more second insulating layers, respectively.

12. The printed circuit board according to claim 11, further comprising:
a first resist layer disposed on an upper surface of a first insulating layer disposed on an uppermost side of the one or more first insulating layers, and having a first opening exposing at least a portion of a third wiring layer disposed on an uppermost side of the one or more third wiring layers; and
a second resist layer disposed on a lower surface of a second insulating layer disposed on a lowermost side of the one or more second insulating layers, and having a second opening exposing at least a portion of a fourth wiring layer disposed on a lowermost side of the one or more fourth wiring layers.

13. A printed circuit board comprising:
a through-via including a via metal layer and a first insulating material disposed in at least a portion of a space between portions of the via metal layer;
a glass layer including a first through-portion in which the through-via is disposed;
a second insulating material including a second through-portion in which the through-via and the glass layer are disposed;
a first wiring layer disposed on an upper surface of the glass layer, at least a portion of the first wiring layer being connected to an upper side of the through-via;
a second wiring layer disposed on a lower surface of the glass layer, at least a portion of the second wiring layer being connected to a lower side of the through-via;
a first insulating layer disposed on upper surfaces of each of the glass layer and the second insulating material, and covering at least a portion of the first wiring layer; and
a second insulating layer disposed on lower surfaces of each of the glass layer and the second insulating material, and covering at least a portion of the second wiring layer,
wherein the first and second insulating materials include substantially the same material.

14. The printed circuit board according to claim 13, wherein the first and second insulating materials include an Ajinomoto Build-up Film (ABF).

15. The printed circuit board according to claim 13, further comprising:
a third insulating material including a third through-portion in which the through-via, the glass layer and the second insulating material are disposed,
wherein the third insulating material includes a material different from the first and second insulating materials.

16. The printed circuit board according to claim 15, wherein the third insulating material includes an insulating material of Copper Clad Laminate (CCL).

17. A printed circuit board comprising:
a glass layer having a through-hole penetrating between an upper surface and a lower surface thereof;
a through-via including a via metal layer disposed on a wall surface of the through-hole and a first insulating material disposed in at least a portion of a space between portions of the via metal layer in the through-hole;
a first wiring layer disposed on the upper surface of the glass layer, at least a portion of the first wiring layer being connected to an upper side of the through-via;
a second wiring layer disposed on the lower surface of the glass layer, at least a portion of the second wiring layer being connected to a lower side of the through-via; and
a second insulating material including a through-hole in which the glass layer is disposed and being in contact with the glass layer,
wherein upper surfaces of each of the glass layer, the first insulating material, the second insulating material, and the via metal layer are substantially coplanar with each other.

18. The printed circuit board according to claim 17, wherein lower surfaces of each of the glass layer, the first insulating material, the second insulating material, and the via metal layer are substantially coplanar to each other.

19. The printed circuit board according to claim 17, wherein the glass layer includes plate glass.

20. The printed circuit board according to claim 17, wherein the via metal layer includes a first seed layer disposed on the wall surface of the through-hole and a first metal layer disposed on a side surface of the first seed layer,
the first wiring layer includes a second seed layer disposed on the upper surface of the glass layer and a second metal layer disposed on an upper surface of the second seed layer, and
the second wiring layer includes a third seed layer disposed on the lower surface of the glass layer and a third metal layer disposed on a lower surface of the third seed layer.

21. The printed circuit board according to claim 20, wherein the second seed layer covers at least a portion of upper surfaces of each of the first seed layer, the first metal layer, and the first insulating material, and
the third seed layer covers at least a portion of lower surfaces of each of the first seed layer, the first metal layer, and the first insulating material.

22. The printed circuit board according to claim 17, further comprising:
a third insulating material having a through-hole in which the second insulating material is disposed and being in contact with the second insulating layer.
